(19) United States
(12) Patent Application Publication
(10) Pub. No.: US 2026/0173702 A1
(43) Pub. Date: Jun. 18, 2026

(54) DISPLAY DEVICE

(71) Applicant: LG Display Co., Ltd., Seoul (KR)

(72) Inventor: Jaeyoung KWAK, Paju-si (KR)

(73) Assignee: LG Display Co., Ltd., Seoul (KR)

(21) Appl. No.: 19/367,564

(22) Filed: Oct. 23, 2025

(30) Foreign Application Priority Data
Dec. 12, 2024 (KR) 10-2024-0184578

(51) Int. Cl. H10K 59/38; H10K 59/122; H10K 59/35; H10K 59/80

(52) U.S. Cl. CPC H10K 59/38; H10K 59/122; H10K 59/35; H10K 59/8792

(57) ABSTRACT

A display device can include a plurality of sub-pixels having a first sub-pixel and a second sub-pixel, a bank disposed in a non-emission area, and a black matrix disposed in the non-emission area. The first sub-pixel and the second sub-pixel are configured to emit different color light from each other, Further, a width of the bank in the first sub-pixel is greater than a width of the black matrix in the first sub-pixel, and a width of the bank in the second sub-pixel is smaller than a width of the black matrix in the second sub-pixel.

### CROSS-REFERENCE TO RELATED APPLICATIONS

This application claims priority to Korean Patent Application No. 10-2024-0184578, filed in the Republic of Korea on Dec. 12, 2024, which is hereby incorporated by reference in its entirety.

### BACKGROUND

### Field of Technology

The present disclosure relates to an apparatus and particularly to, for example, without limitation, a display device.

### Description of the Related Art

As an information society develops, a demand for a display device for displaying an image is increasing in various forms. Accordingly, various display devices such as a liquid crystal display (LCD), a plasma display panel (PDP), and an organic light emitting display (OLED) have recently been used.

Among the display devices, the organic light emitting display device is a self-luminous type, has better viewing angle and contrast ratio than the liquid crystal display (LCD), and has an advantage of being lightweight and thin because a separate backlight is not required and power consumption is advantageous. In addition, the organic light emitting display device has an advantage of being driven with a low DC voltage, having a fast response speed, and especially low manufacturing cost.

Recently, in order to improve an efficiency of a light emitting device, a display device to which a polarizing plate is removed and a color filter is applied is used. Since the polarizing plate is removed, however, a problem of increasing a reflectance due to external light can occur.

### SUMMARY OF THE DISCLOSURE

The present disclosure has been made in view of the above problems and other limitations associated with the related art.

Accordingly, it is an aspect of the present disclosure to provide a display device capable of reducing reflectance by external light

In accordance with an aspect of the present disclosure, the above and other technical effects can be accomplished by the provision of a display device comprising a plurality of sub-pixels including an emission area and a non-emission area surrounding the emission area, wherein each of the plurality of sub-pixels include a planarization layer on a substrate, a bank disposed on the planarization layer in the non-emission area, a light emitting layer on the planarization layer in the emission area, a black matrix disposed on the bank and overlapping the bank, and a color filter disposed on the light emitting layer and overlapping the light emitting layer, wherein the plurality of sub-pixels includes a first sub-pixel and a second sub-pixel, and the first sub-pixel and the second sub-pixel emit different light from each other, and wherein a width of the bank is greater than a width of the black matrix in the first sub-pixel, and a width of the bank is smaller than a width of the black matrix in the second sub-pixel.

In addition, in accordance with an aspect of the present disclosure, the above and other technical effects can be accomplished by the provision of a display device comprising a plurality of sub-pixels including an emission area and a non-emission area surrounding the emission area, wherein each of the plurality of sub-pixels include a planarization layer on a substrate, a bank disposed on the planarization layer in the non-emission area, a light emitting layer on the planarization layer in the emission area, a black matrix disposed on the bank and overlapping the bank, and a color filter disposed on the light emitting layer and overlapping the light emitting layer, wherein the plurality of sub-pixels includes a first sub-pixel and a second sub-pixel, and the first sub-pixel and the second sub-pixel emit different light from each other, and wherein a width of the light emitting layer is smaller than a width of the color filter in the first sub-pixel, and a width of the light emitting layer is greater than a width of the color filter in the second sub-pixel.

It is to be understood that both the foregoing general description and the following detailed description are examples and explanatory and are intended to provide further explanation of the inventive concepts as claimed

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description explain the principle of the disclosure. In the drawings:

FIG. 1 is a plan view of a display device according to one or more embodiments of the present disclosure.

FIG. 2 is a plan view of one pixel according to one or more embodiments of the present disclosure.

FIG. 3 is a cross-sectional view of one sub-pixel of a display device according to embodiments of the present disclosure.

FIG. 4 is a cross-sectional view of one sub-pixel of a display device according to embodiments of the present disclosure.

FIG. 5 is a cross-sectional view of one pixel of a display device according to embodiments of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

Advantages and features of the present disclosure, and implementation methods thereof, will be clarified through the following examples described with reference to the accompanying drawings. The present disclosure may, however, be embodied in different forms and should not be construed as limited to the examples set forth herein. Rather, these examples are provided so that the specification of the present disclosure will be thorough, complete, and fully convey the scope of the present disclosure to those skilled in the art.

A shape, a size, a ratio, an angle, and a number disclosed in the accompanying drawings for describing the examples of the present disclosure are merely illustrative and, thus, the present disclosure is not limited to the illustrated details. Unless stated otherwise, like reference numerals refer to like elements throughout the specification. In the following description, when the detailed description of the relevant known function or configuration is determined to unnecessarily obscure an important point of the present disclosure, the detailed description will be omitted. In a case where terms such as ‘comprise’, ‘have’, and ‘include’ described in the present disclosure are used, another portion can be added unless ‘only’ is used. The terms of a singular form can include plural forms unless referred to the contrary.

In interpreting the components, it is interpreted as including an error range even if there is no separate explicit description of an error range.

In describing a position relationship, for example, when the position relationship is described using terms such as ‘upon’, ‘above’, ‘below’ and ‘next to’, one or more portions can be disposed between two other portions unless ‘just’ or ‘direct’ is used. The terms, such as “below,” “lower,” “above,” “upper”, and the like, can be used herein to describe a relationship between elements as illustrated in the drawings. It will be understood that the terms are spatially relative and based on the orientation depicted in the drawings.

A description of a time relationship can include a case in which the temporal precedence relationship is described as “after”, “following”, or “before”, etc., and is not continuous unless “right away” or “directly”, is used.

Although the terms such as first, second, and the like are used to describe various components, these components are not limited by these terms. These terms are used only to distinguish one component from another. Therefore, a first component mentioned below can be a second component within a technical idea of a present disclosure.

It will be understood that, although the terms such as “first,” “second,” “A,” “B,” “(a),” and “(b)”, etc., can be used herein to describe various elements, these elements should not be limited by these terms. These terms are only used to distinguish one element from another. For example, a first element could be termed a second element, and, similarly, a second element could be termed a first element, without departing from the scope of the present disclosure. Further, the term “can” fully encompasses all the meanings and coverages of the term “may” and vice versa.

Features of each of the various examples of the present disclosure can be partially or entirely coupled or combined with each other, technically various interworking and driving are possible, and each of the examples can be independently implemented with respect to each other or can be implemented together in a related relationship.

Hereinafter, embodiments of the present disclosure will be described in detail with reference to the accompanying drawings. All the components of each display device/apparatus according to all embodiments of the present disclosure are operatively coupled and configured.

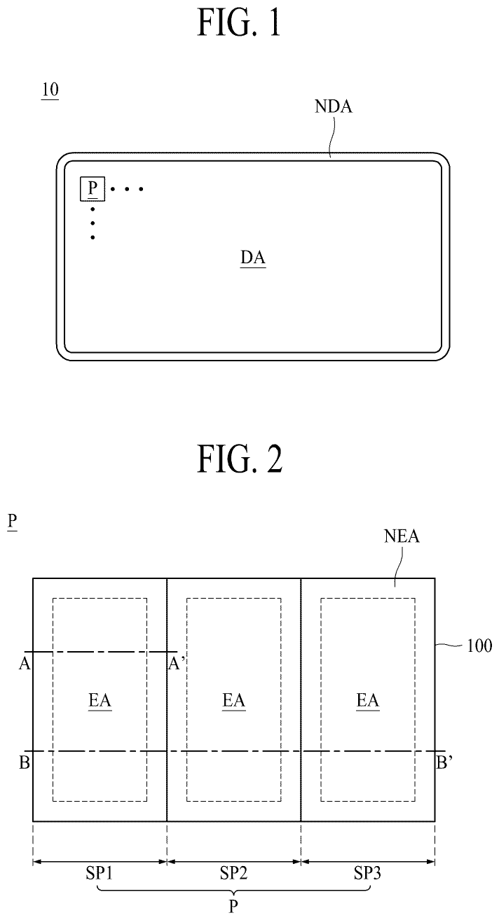

FIG. 1 is a plan view of a display device according to one or more embodiments of the present disclosure.

Referring to FIG. 1, a display device 10 according to an embodiment of the present disclosure can include a display area DA and a non-display area NDA surrounding the display area DA. The display area DA is an area in which an image can be displayed, and the non-display area NDA is an area in which an image is not displayed. The non-display area NDA can surround the display area DA entirely or only in part(s).

The display area DA can include a plurality of pixels P. The plurality of pixels P can be arranged in a matrix form consisting of a plurality of rows and columns. In addition, the non-display area NDA can include a plurality of wirings, pads, driving circuits, etc. for driving the plurality of pixels P. As such, the display device 10 includes all components to operate as a display device.

FIG. 2 is a plan view of one pixel of a display device according to an embodiment of the present disclosure. The pixel configuration of FIG. 2 can be applied in each pixel of the display device 10 or other display devices.

Referring to FIG. 2, one pixel P can include a first sub-pixel SP1, a second sub-pixel SP2, and a third sub-pixel SP3. The first sub-pixel SP1, the second sub-pixel SP2, and the third sub-pixel SP3 can emit different light (e.g., different color light) from each other. For example, the first sub-pixel SP1 can emit red light, the second sub-pixel SP2 can emit green light, and the third sub-pixel SP3 can emit blue light, but the present disclosure is not limited thereto. In addition, FIG. 2 shows that one pixel P includes three sub-pixels SP1 to SP3, but is not limited thereto. For example, one pixel P can include more than three sub-pixels.

The first sub-pixel SP1, the second sub-pixel SP2, and the third sub-pixel SP3 can be disposed on a first substrate 100. Each of the first sub-pixel SP1, the second sub-pixel SP2, and the third sub-pixel SP3 can include an emission area EA and a non-emission area NEA surrounding the emission area EA. The emission area EA is an area capable of emitting light, and the non-emission area NEA is an area that does not emit light.

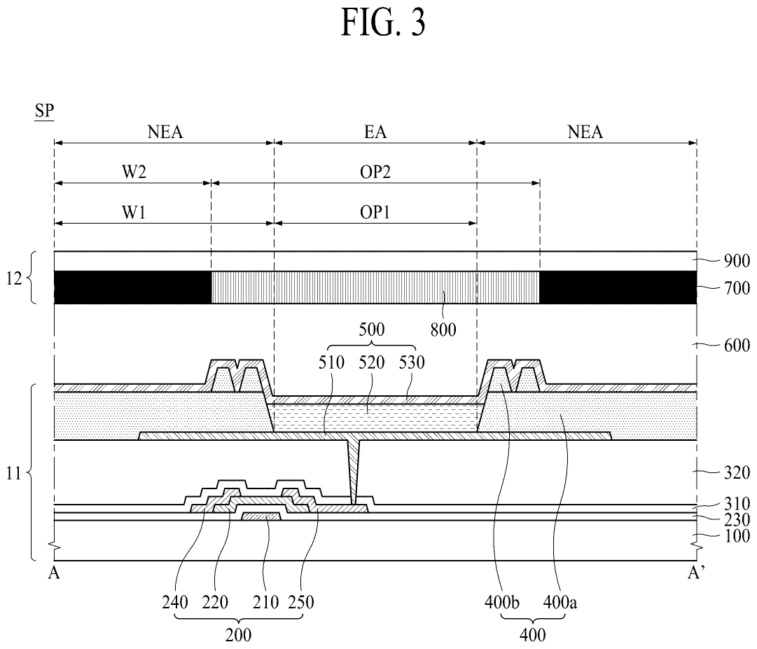

FIG. 3 is a cross-sectional view of one sub-pixel SP of a display device according to embodiments of the present disclosure. In detail, FIG. 3 is a cross-sectional view of one sub-pixel SP taken along line A-A′ illustrated in FIG. 2. FIG. 3 illustrates a cross-sectional view of the first sub-pixel SP1, but the present disclosure is not limited thereto. For example, FIG. 3 can be a cross-sectional view of any one of the second sub-pixel SP2 and the third sub-pixel SP3 illustrated in FIG. 2. The sub-pixel configuration of FIG. 3 can be applied in each sub-pixel of the display device 10 or other display devices according to examples of the present disclosure.

Referring to FIG. 3, one sub-pixel SP according to an embodiment of the present disclosure can include a circuit unit 11 and a filter unit 12. The circuit unit 11 can include a first substrate 100, a thin film transistor 200, a passivation layer 310, a planarization layer 320, a bank 400, and a light emitting device 500. The filter unit 12 can include a black matrix 700, a color filter 800, and a second substrate 900. The circuit unit 11 and the filter unit 12 can be bonded to each other by an encapsulation layer 600.

The first substrate 100 can be made of glass or plastic, but is not limited thereto. The display device according to an embodiment of the present disclosure can be configured in a top emission type in which light is emitted upward. Therefore, as a material of the first substrate 100, not only a transparent material but also an opaque material can be used.

The thin film transistor 200 can be disposed on the first substrate 100. The thin film transistor 200 can include a gate electrode 210, a semiconductor layer 220, a gate insulating layer 230, a source electrode 240, and a drain electrode 250.

The gate electrode 210 of the thin film transistor 200 can be disposed on the first substrate 100. In addition, the semiconductor layer 220 can be disposed on the gate electrode 210. The semiconductor layer 220 can include a poly-silicon semiconductor or an oxide semiconductor. In addition, when the semiconductor layer 220 includes the oxide semiconductor, at least one oxide of indium-gallium-zinc-oxide (IGZO), indium-gallium-tin-oxide (IGTO), and indium-gallium-oxide (IGO) can be included.

The gate insulating layer 230 for insulating the gate electrode 210 and the semiconductor layer 220 can be disposed between the gate electrode 210 and the semiconductor layer 220. The gate insulating layer 230 can be formed of a single layer of silicon nitride (SiNx) or silicon oxide (SiOx), or multiple layers thereof. In addition, FIG. 3 illustrates a bottom gate structure in which the semiconductor layer 220 is disposed on the gate electrode 210, but is not limited thereto. For example, a top gate structure in which the gate electrode 210 is disposed on the semiconductor layer 220 can be disclosed.

The source electrode 240 and the drain electrode 250 can be disposed on the semiconductor layer 220 while facing each other. In addition, the passivation layer 310 can be disposed on the source electrode 240 and the drain electrode 250. A contact hole exposing a portion of the drain electrode 250 can be disposed in the passivation layer 310. In addition, the passivation layer 310 can be formed of an inorganic insulating material such as silicon oxide (SiOx), silicon nitride (SiNx), silicon oxynitride (SiOxNy), or the like.

The planarization layer 320 can be disposed on the thin film transistor 200. The planarization layer 320 can compensate for a step difference caused by the thin film transistor 200 to form a flat upper area of the thin film transistor 200. In addition, the planarization layer 320 can be formed of an organic insulating material such as an acrylic resin, an epoxy resin, a phenolic resin, a polyamide resin, or a polyimide resin.

The bank 400 can be disposed on the planarization layer 320 and in the non-emission area NEA. The bank 400 can expose a partial area of the planarization layer 320. An area of the planarization layer 320 exposed by the bank 400 can be a first opening area OP1. For example, the bank 400 can surround the first opening area OP1.

The first opening area OP1 can overlap an entire emission area EA, and may not overlap the non-emission area NEA. For example, a width of the first opening area OP1 can be the same as a width of the emission area EA. In addition, a width of the bank 400 can be a first width W1. The width of the bank 400 can be a width of an area in which a bottom surface of the bank 400 and the planarization layer 320 overlap. Referring to FIG. 3, one side of the bottom surface of the bank 400 is in contact with an end of the sub-pixel SP, and can overlap the planarization layer 320. In addition, the other side of the bottom surface of the bank 400 is in contact with a top surface of the first electrode 510, and can overlap the planarization layer 320. In this case, the width of the bank 400 can be a distance from one end of the bank 400 to the other end of the bank 400. In this case, the first width W1 can be the same as a width of the non-emission area NEA. Accordingly, the widths of the emission area EA and the non-emission area NEA can be defined according to an area in which the bank 400 is disposed.

The bank 400 can include a lower bank 400a and a plurality of upper banks 400b. The lower bank 400a can be disposed on the planarization layer 320, and the plurality of upper banks 400b can be disposed on the lower bank 400a.

The lower bank 400a can be disposed in the non-emission area NEA. In addition, the lower bank 400a can surround the first opening area OP1. The first width W1, which is the width of the bank 400, can be a width of the lower bank 400a.

The plurality of upper banks 400b can be disposed in the non-emission area NEA. In particular, the plurality of upper banks 400b can be disposed in the non-emission area NEA adjacent to the emission area EA.

On the lower bank 400a, the plurality of upper banks 400b can be spaced apart from each other. A sum of widths of the plurality of upper banks 400b can be smaller than a width of an upper surface of the lower bank 400a. In addition, upper surfaces of the plurality of upper banks 400b can be flat, but are not limited thereto. For example, a plurality of protrusion portions can be further disposed on the upper surfaces of the plurality of upper banks 400b. Alternatively, a plurality of concave portions can be further disposed on the upper surfaces of the plurality of upper banks 400b. Alternatively, the plurality of upper banks 400b can include at least one uneven portion. Accordingly, light incident to the plurality of upper banks 400b can be diffusely reflected.

The lower bank 400a and the plurality of upper banks 400b can include an organic insulating material such as an acryl resin, an epoxy resin, a phenolic resin, a polyamide resin, a polyimide resin, etc. Alternatively, the lower bank 400a and the plurality of upper banks 400b can include an inorganic insulating material such as silicon oxide (SiOx), silicon nitride (SiNx), silicon oxynitride (SiOxNy), etc. In this case, the lower bank 400a and the plurality of upper banks 400b can further include a material absorbing light. For example, the lower bank 400a and the plurality of upper banks 400b can be black banks.

The lower bank 400a and the plurality of upper banks 400b can be made of the same material. In this case, the bank 400 can be integrally disposed and can have a shape in which a plurality of protrusions are disposed on an upper surface thereof. Alternatively, the bank 400 can be integrally disposed and can have a shape in which a plurality of concave portions are disposed on the upper surface thereof.

The light emitting device 500 can be disposed on the planarization layer 320. The light emitting device 500 can include a first electrode 510, a light emitting layer 520, and a second electrode 530.

The first electrode 510 is disposed on the planarization layer 320 and can function as an anode of the display device. The first electrode 510 can be electrically connected to the thin film transistor 200 through a contact hole disposed in the passivation layer 310 and the planarization layer 320. Although FIG. 3 illustrates that the first electrode 510 is electrically connected to the drain electrode 250, the present disclosure is not limited thereto. For example, the first electrode 510 can be electrically connected to the source electrode 240.

The first electrode 510 can be disposed on an entire surface of the first opening area OP1. For example, the first electrode 510 can be disposed in the entire emission area EA and in a partial area of the non-emission area NEA. In addition, an end of the first electrode 510 can be covered by the bank 400.

The first electrode 510 can include a transparent conductive material such as indium tin oxide (ITO) or indium zinc oxide (IZO). Alternatively, the first electrode 510 can include a metal material such as aluminum (Al), silver (Ag), copper (Cu), molybdenum (Mo), titanium (Ti), tungsten (W), or chromium (Cr), or an alloy thereof. Furthermore, the first electrode 510 is illustrated as a single layer, but can be formed as multiple layers.

The light emitting layer 520 can be disposed on the first electrode 510. The light emitting layer 520 can be disposed on the entire surface of the first opening area OP1. For example, the light emitting layer 520 can cover an entire upper surface of the first electrode 510 not covered by the bank 400. In addition, the light emitting layer 520 can be disposed on the entire emission area EA and a partial area of the non-emission area NEA.

The light emitting layer 520 can include a hole transporting layer, an emission layer, and an electron transporting layer. In this case, when a voltage is applied to the first electrode 510 and the second electrode 530, holes and electrons move to the emission layer through the hole transport layer and the electron transport layer, respectively, and can combine with each other in the emission layer to emit light.

The second electrode 530 can be disposed on the light emitting layer 520. The second electrode 530 can function as a cathode of the display device. The second electrode 530 can be disposed on the entire surface of the first opening area OP1. In addition, the second electrode 530 can be disposed on the bank 400. For example, the second electrode 530 can be disposed in the entire emission area EA and in a partial area of the non-emission area NEA. In addition, the second electrode 530 can be disposed in the entire non-emission area NEA.

Since the display device according to an embodiment of the present disclosure is configured in a top emission type, the second electrode 530 can include a transparent conductive material such as an indium tin oxide (ITO) or an indium zinc oxide (IZO) to transmit light emitted from the light emitting layer 520 upward.

In this case, a width of the light emitting device 500 can be a width of an area in which the first electrode 510, the light emitting layer 520, and the second electrode 530 overlap each other in the first opening area OP1. For example, an area in which the light emitting device 500 and the bank 400 overlap each other can be excluded from the width of the light emitting device 500.

The encapsulation layer 600 can be disposed on the light emitting device 500. The encapsulation layer 600 can compensate for a step difference caused by the light emitting device 500. The encapsulation layer 600 can include an organic insulating material such as an acrylic resin, an epoxy resin, a phenolic resin, a polyamide resin, or a polyimide resin. The encapsulation layer 600 can be disposed in the entire emission area EA and the entire non-emission area NEA.

The black matrix 700, the color filter 800, and the second substrate 900 can be disposed on the encapsulation layer 600.

The second substrate 900 can be disposed in the emission area EA and the non-emission area NEA. The second substrate 900 can be made of glass or plastic, but is not limited thereto. Since the display device according to an embodiment of the present disclosure is made of a top emission type, a transparent material can be used as a material of the second substrate 900.

The black matrix 700 can be disposed between the second substrate 900 and the encapsulation layer 600. The black matrix 700 can be disposed in the non-emission area NEA. The black matrix 700 can expose a partial area of the second substrate 900. An area of the second substrate 900 exposed by the black matrix 700 can be a second opening area OP2. For example, the black matrix 700 can surround the second opening area OP2.

The second opening area OP2 can overlap the entire emission area EA and a partial area of the non-emission area NEA. For example, a width of the second opening area OP2 can be greater than the width of the emission area EA. In addition, the width of the second opening area OP2 can be greater than the width of the first opening area OP1.

The width of the black matrix 700 can be a second width W2. In this case, the second width W2 can be less than the width of the non-emission area NEA. Further, the second width W2 can be less than the first width W1.

The color filter 800 can be disposed between the second substrate 900 and the encapsulation layer 600. The color filter 800 can be disposed on an entire surface of the second opening area OP2. For example, the color filter 800 can be disposed in the entire emission area EA and a partial area of the non-emission area NEA.

FIG. 3 discloses that the plurality of upper banks 400b overlap the color filter 800 and do not overlap the black matrix 700 in the non-emission area NEA, but is not limited thereto. For example, the plurality of upper banks 400b can also be disposed in an area overlapping the black matrix 700. In this case, diffuse reflection can be effectively performed by the plurality of upper banks 400b.

The color filter 800 can transmit only light of a specific wavelength band. For example, the color filter 800 can transmit only anyone light of red, green, and blue. Accordingly, the present disclosure can improve an efficiency of the light emitting device 500 by removing a polarizing plate and using the color filter 800.

As the polarizing plate is removed from the display device, reflectance by external light can increase. To minimize or reduce reflectance by external light, the present disclosure discloses a pull-back structure. Specifically, the width of the bank 400 can be increased by forming the width of the light emitting layer 520 to be smaller than the width of the color filter 800. Accordingly, it is possible to minimize or reduce an incident of external light into the display device.

In addition, the present disclosure discloses the bank 400 including the lower bank 400a and the plurality of upper banks 400b. In particular, the plurality of upper banks 400b can be disposed in an area overlapping the color filter 800 and not overlapping with the black matrix 700. When external light is incident through the color filter 800, the incident external light can be diffusely reflected by the plurality of upper banks 400b. Further, the diffusely reflected external light can be absorbed into the black matrix 700. Accordingly, external light can be further prevented or reduce from being incident into the display device. Accordingly, reflectance by external light can be reduced.

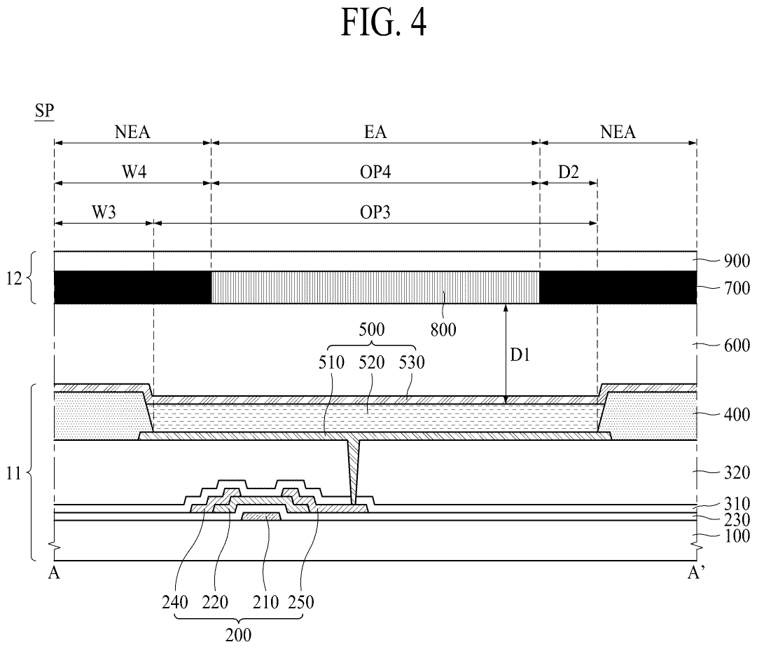

FIG. 4 is a cross-sectional view of one sub-pixel SP of a display device according to embodiments of the present disclosure. The sub-pixel configuration of FIG. 4 can be applied in each sub-pixel of the display device 10 or other display devices according to examples of the present disclosure.

Compared with FIG. 3, FIG. 4 illustrates substantially the same structure except for the structure of the bank 400. Accordingly, the same reference numerals are used for the same components as the sub-pixel SP shown in FIG. 3, and repeated descriptions thereof are omitted or may be briefly provided.

Referring to FIG. 4, the bank 400 can be disposed on the planarization layer 320, and the bank 400 can be disposed in the non-emission area NEA. An upper surface of the bank 400 can be flat. The bank 400 can expose a partial area of the planarization layer 320. An area of the planarization layer 320 exposed by the bank 400 can be a third opening area OP3. For example, the bank 400 can surround the third opening area OP3.

The third opening area OP3 can overlap the entire emission area EA and a partial area of the non-emission area NEA. For example, a width of the third opening area OP3 can be greater than the width of the emission area EA. In addition, the width of the bank 400 can be a third width W3. In this case, the third width W3 can be less than the width of the non-emission area NEA.

An area of the second substrate 900 exposed by the black matrix 700 can be a fourth opening area OP4. For example, the black matrix 700 can surround the fourth opening area OP4. The fourth opening area OP4 overlaps the entire emission area EA, and may not overlap the non-emission area NEA. For example, a width of the fourth opening area OP4 can be the same as the width of the emission area EA. In addition, the width of the fourth opening area OP4 can be smaller than the width of the third opening area OP3.

A width of the black matrix 700 can be a fourth width W4. In this case, the fourth width W4 can be the same as the width of the non-emission area NEA. Further, the fourth width W4 can be greater than the third width W3. Accordingly, the widths of the emission area EA and the non-emission area NEA of the sub-pixel SP can be defined according to an area in which the black matrix 700 is disposed.

The color filter 800 can be disposed between the second substrate 900 and the encapsulation layer 600. The color filter 800 can be disposed on the entire surface of the fourth opening area OP4. For example, the color filter 800 can be disposed in the entire emission area EA.

FIG. 3 illustrates the pull-back structure for improving reflectance by external light. In this case, as the width of the light emitting layer 520 decreases, a lifespan of the light emitting device 500 can decrease.

However, in FIG. 4, the present disclosure discloses a pull-in structure in which the width of the light emitting layer 520 is greater than the width of the color filter 800. Accordingly, by increasing the width of the light emitting layer 520, desired luminance can be obtained even when a small voltage is applied. Accordingly, the lifespan of the light emitting device 500 can be improved.

In addition, referring to FIG. 4, a distance from an upper surface of the light emitting layer 520 to a lower surface of the color filter 800 can be referred to as a first distance D1, and a distance from one end of the fourth opening area OP4 to one end of the third opening area OP3 can be referred to as a second distance D2. In this case, in order to maintain luminance and color characteristics according to a viewing angle, the first distance D1 the and second distance D2 can satisfy Equation 1 below. In addition, θ can be a value of 60° or more and 85° or less.

$$D 2 = \frac{D 1}{tan θ} \qquad Equation l$$

As described above, the pull-back structure disclosed in FIG. 3 has an effect of reducing reflectance by external light by minimizing or reducing the incident of external light into the display device. In addition, the pull-in structure disclosed in FIG. 4 has an effect of improving the lifespan of the light emitting device 500. Accordingly, an efficiency of the display device can be maximized or reducing by selectively applying either the structure of FIG. 3 or the structure of FIG. 4 to each sub-pixel SP

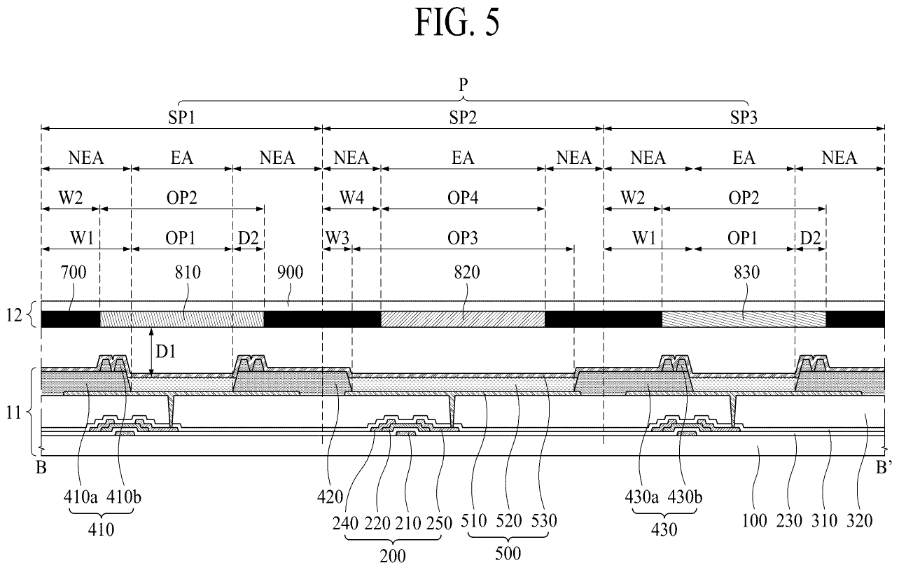

FIG. 5 is a cross-sectional view of one pixel P of a display device according to embodiments of the present disclosure. Specifically, it is a cross-sectional view of one pixel P taken along line B-B′ shown in FIG. 2. The pixel configuration of FIG. 5 can be applied in each pixel of the display device 10 or other display devices according to examples of the present disclosure.

Referring to FIG. 5, the first sub-pixel SP1 and the third sub-pixel SP3 disclose a structure of the embodiment of FIG. 3, and the second sub-pixel SP2 disclose the structure of the embodiment of FIG. 4.

A first width W1 that is a width of the bank 400 of each of the first sub-pixel SP1 and the third sub-pixel SP3 can be different from a third width W3 that is a width of the bank 400 of the second sub-pixel SP2. Specifically, the first width W1 that is the width of the bank 400 of each of the first sub-pixel SP1 and the third sub-pixel SP3 can be greater than the third width W3 that is the width of the bank 400 of the second sub-pixel SP2.

A second width W2, which is the width of the black matrix 700 of each of the first sub-pixel SP1 and the third sub-pixel SP3, can be the same as a fourth width W4, which is the width of the black matrix 700 of the second sub-pixel SP2.

Accordingly, the widths of the emission area EA of the first sub-pixel SP1 and the third sub-pixel SP3 can be different from the width of the emitting area EA of the second sub-pixel SP2. In detail, the widths of the emission area EA of the first sub-pixel SP1 and the third sub-pixel SP3 can be smaller than the width of the emission area EA of the second sub-pixel SP2.

A height of the lower bank 410a of the first sub-pixel SP1 can be the same as a height of the bank 420 of the second sub-pixel SP2. In addition, the height of the lower bank 410a of the first sub-pixel SP1 can be the same as a height of the lower bank 430a of the third sub-pixel SP3. For example, since the lower banks 410a and 430a of the first sub-pixel SP1 and the third sub-pixel SP3 and the bank 420 of the second sub-pixel SP2 have the same height and can be continuously disposed.

Meanwhile, the first sub-pixel SP1 and the third sub-pixel SP3 can further include the plurality of upper banks 410b and 430b disposed on the lower banks 410a and 430a. Accordingly, heights of the banks 410 and 430 of the first sub-pixel SP1 and the third sub-pixel SP3 can be higher than a height of the bank 420 of the second sub-pixel SP2. Accordingly, the first sub-pixel SP1 and the third sub-pixel SP3 can more effectively diffusely reflect incident light by the plurality of upper banks 410b and 430b disposed relatively high.

The first sub-pixel SP1 can include a light emitting device 500 that generates red light and a first color filter 810 that transmits red light. Accordingly, the first sub-pixel SP1 can emit red light.

The second sub-pixel SP2 can include a light emitting device 500 that generates green light and a second color filter 820 that transmits green light. Accordingly, the second sub-pixel SP2 can emit green light.

The third sub-pixel SP3 can include a light emitting device 500 that generates blue light and a third color filter 830 that transmits blue light. Accordingly, the third sub-pixel SP3 can emit blue light.

Meanwhile, a material of the light emitting layer 520 can be different according to a wavelength band of generated light. Accordingly, a lifespan of the light emitting device 500 can be different according to the wavelength band of generated light. Typically, the light emitting device 500 that generates green light can have a shorter lifespan than the light emitting device 500 that generates red and blue light.

To this end, the present disclosure can improve the lifespan of the light emitting device 500 by applying the pull-in structure to the second sub-pixel SP2 including the light emitting device 500 that generates green light.

In addition, in the present disclosure, by applying the pull-back structure to the first sub-pixel SP1 and the third sub-pixel SP3 including the light emitting device 500 that generates red and blue light with the relatively long lifespan, reflectance by external light can be reduced or prevented.

Therefore, in the present disclosure, while maintaining the lifespan of the first sub-pixel SP1, the second sub-pixel SP2, and the third sub-pixel SP3 as uniform as possible, reflectance by external light can be reduced or prevented.

It will be apparent to those skilled in the art that the present disclosure described above is not limited by the above-described embodiments and the accompanying drawings and that various substitutions, modifications and variations can be made in the present disclosure without departing from the technical idea or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a plurality of sub-pixels, each including an emission area and a non-emission area surrounding the emission area,
wherein each of the plurality of sub-pixels further includes:
a planarization layer on a substrate;
a bank disposed on the planarization layer in the non-emission area;
a light emitting layer on the planarization layer in the emission area;
a black matrix disposed on the bank and overlapping the bank; and
a color filter disposed on the light emitting layer and overlapping the light emitting layer,
wherein the plurality of sub-pixels includes a first sub-pixel and a second sub-pixel, and the first sub-pixel and the second sub-pixel are configured to emit different color light from each other, and
wherein a width of the bank of the first sub-pixel is greater than a width of the black matrix in the first sub-pixel, and a width of the bank of the second sub-pixel is smaller than a width of the black matrix in the second sub-pixel.

2. The display device of claim 1, wherein the width of the bank of the first sub-pixel is greater than the width of the bank of the second sub-pixel.

3. The display device of claim 1, wherein a width of the emission area of the first sub-pixel is greater than a width of the emission area of the second sub-pixel.

4. The display device of claim 1, wherein a width of the non-emission area in the first sub-pixel is a same as the width of the bank in the first sub-pixel, and a width of the non-emission area in the second sub-pixel is a same as a width of the black matrix in the second sub-pixel.

5. The display device of claim 1, wherein the first sub-pixel includes a first opening area surrounded by the bank and a second opening area surrounded by the black matrix,
wherein the second sub-pixel includes a third opening area surrounded by the bank and a fourth opening area surrounded by the black matrix,
wherein a width of the first opening area is smaller than a width of the second opening area, and
wherein a width of the third opening area is greater than a width of the fourth opening area.

6. The display device of claim 5, wherein an emission layer of the light emitting layer is disposed in an entire area of the first opening area and an entire area of the third opening area, and
wherein the color filter is provided in an entire area of the second opening area and an entire area of the fourth opening area.

7. The display device of claim 5, wherein a width of emission area in the first sub-pixel is a same as the width of the first opening area in the first sub-pixel, and
wherein a width of the emission area in the second sub-pixel is a same as the width of the fourth opening area in the second sub-pixel.

8. The display device of claim 1, wherein in the first sub-pixel, the bank includes a lower bank disposed on the planarization layer and a plurality of upper banks disposed on the lower bank, and
wherein in the first sub-pixel, the plurality of upper banks covers a partial area of the lower bank and overlaps the non-emission area adjacent to the emission area.

9. The display device of claim 8, wherein the plurality of upper banks overlaps the color filter and does not overlap the black matrix.

10. The display device of claim 1, wherein the light emitting layer of the first sub-pixel is configured to generate red or blue light, and the light emitting layer of the second sub-pixel is configured to generate green light.

11. The display device of claim 1, wherein the plurality of sub-pixels further includes a third sub-pixel,
wherein the third sub-pixel is configured to emit color light different from color light emitted by the first sub-pixel and the second sub-pixel,
wherein a shape of the bank of the third sub-pixel is a same as a shape of the bank of the first sub-pixel, and
wherein the shape of the bank of the third sub-pixel is different from a shape of the bank of the second sub-pixel.

12. The display device of claim 11, wherein the light emitting layer of the first sub-pixel is configured to generate red light, the light emitting layer of the second sub-pixel is configured to generate green light, and the light emitting layer of the third sub-pixel is configured to generate blue light.

13. A display device comprising:
a plurality of sub-pixels, each including an emission area and a non-emission area surrounding the emission area,
wherein each of the plurality of sub-pixels further includes:
a planarization layer on a substrate;
a bank disposed on the planarization layer in the non-emission area;
a light emitting layer on the planarization layer in the emission area;
a black matrix disposed on the bank and overlapping the bank; and
a color filter disposed on the light emitting layer and overlapping the light emitting layer,
wherein the plurality of sub-pixels includes a first sub-pixel and a second sub-pixel, and the first sub-pixel and the second sub-pixel are configured to emit different color light from each other, and
wherein a width of the light emitting layer in the first sub-pixel is smaller than a width of the color filter in the first sub-pixel, and a width of the light emitting layer in the second sub-pixel is greater than a width of the color filter in the second sub-pixel.

14. The display device of claim 13, wherein the first sub-pixel includes a first opening area surrounded by the bank and a second opening area surrounded by the black matrix,
wherein the second sub-pixel includes a third opening area surrounded by the bank and a fourth opening area surrounded by the black matrix,
wherein a width of the first opening area is smaller than a width of the second opening area, and
wherein a width of the third opening area is greater than a width of the fourth opening area.

15. The display device of claim 14, wherein the light emitting layer is disposed in an entire area of the first opening area and an entire area of the third opening area, and
wherein the color filter is disposed in an entire area of the second opening area and an entire area of the entire fourth opening area.

16. The display device of claim 14, wherein a width of the emission area is a same as the width of the first opening area in the first sub-pixel, and
wherein a width of the emission area is a same as the width of the fourth opening area in the second sub-pixel.

17. The display device of claim 13, wherein in the first sub-pixel, the bank includes a lower bank disposed on the planarization layer and a plurality of upper banks disposed on the lower bank, and
wherein in the first sub-pixel, the plurality of upper banks covers a partial area of the lower bank and overlaps the non-emission area adjacent to the emission area.

18. The display device of claim 17, wherein the plurality of upper banks overlaps the color filter and does not overlap the black matrix.

19. The display device of claim 13, wherein the color filters in the plurality of sub-pixels have a same width, while the light emitting layers in some of the plurality of sub-pixels have a first width while the light emitting layers in remaining ones of the plurality of sub-pixels have a second width different from the first width.
